(19) United States
(12) Patent Application Publication
(10) Pub. No.: US 2024/0055561 A1
(43) Pub. Date: Feb. 15, 2024

(54) OPTOELECTRONIC DEVICE AND MANUFACTURING METHOD

(71) Applicant: ALEDIA, Echirolles (FR)

(72) Inventors: Florian DUPONT, Grenoble (FR); Jérôme NAPIERALA, Saint Egreve (FR)

(21) Appl. No.: 18/258,142

(22) PCT Filed: Dec. 17, 2021
(86) PCT No.: PCT/EP2021/086503

§ 371 Date: Jun. 16, 2023

(30) Foreign Application Priority Data
Dec. 17, 2020 (FR) 2013558

(51) Int. Cl. H01L 33/32; H01L 33/00; H01L 33/20

(52) U.S. Cl. CPC H01L 33/32; H01L 33/007; H01L 33/20

(57) ABSTRACT

A method for manufacturing three-dimensional (3D) structures for optoelectronics, each 3D structure including, in a stack along (z), a bottom part bearing on a substrate, an active region configured to emit light radiation, said active region bearing on a top of the bottom part, and a top part bearing on a top of the active region, the method including provision of a substrate carrying a plurality of bottom parts of 3D structures, said bottom parts having distinct tops such that the tops of two adjacent bottom parts are separated from each other by a separation distance ds of less than 180 nm, formation by metalorganic vapour-phase epitaxy (MOVPE) of the active regions on the tops of the bottom parts, formation of the top parts on the tops of the active regions. An embodiment also relates to an optoelectronic device based on a plurality of these 3D structures.

### TECHNICAL FIELD OF THE INVENTION

The invention relates to the field of optoelectronics. It finds a particularly advantageous application in the field of light-emitting diodes based on gallium nitride (GaN) having a three-dimensional structure.

### PRIOR ART

Light emitting diodes (LEDs) typically comprise a so-called active region where radiative recombinations of electron-hole pairs occur, which make it possible to obtain light radiation having a principal wavelength.

For display applications, LEDs can be configured to produce light radiation the principal wavelength of which is located in the blue, or in the green, or in the red.

This principal wavelength depends in particular on the composition of the active region. To produce light radiation in the green or in the red, the active region can typically comprise quantum wells based on InGaN. The more the concentration of indium [In] increases, the more the principal wavelength increases. It may thus be necessary to incorporate a concentration of indium [In] 10% at to obtain an LED emitting in the red.

LEDs based on GaN and are generally manufactured according to a so-called planar technology, which consist in forming, on a base plane of a substrate, a stack of two-dimensional (2D) layers in a direction normal to the base plane.

As illustrated in FIG. 1, this stack can typically comprise, as from the substrate 10, a buffer region 101 made from GaN, an n-doped region 102 of GaN, the active region 103 comprising quantum wells based on InGaN, and a p-doped region 104 of GaN.

A subsequent structuring of this stack, example by lithography/etching steps, then makes it possible to form a plurality of LEDs or micro-LEDs each having a mesa-structure typically comprising a top face 1040 and lateral walls 100 (FIG. 1).

One drawback of this type of mesa structure is related to the subsequent structuring. The lateral walls 100 obtained by etching generally have defects favouring the appearance of non-radiative surface recombinations. The radiative efficiency of the LEDs is reduced.

One solution for reducing defects on the lateral walls consists in directly forming a three-dimensional (3D) structure based on GaN. These 3D structures may be in the form of microwires 2 or nanowires 2 based on GaN and extending mainly in a direction z normal to the substrate 1, as illustrated in FIG. 2. They typically comprise a bottom part 21 bearing on the substrate 1, an active region 22 bearing on the bottom part 21, and a top part 23 bearing on the active region 22, in a stack in the longitudinal direction z.

These 3D structures 2 typically have a so-called axial architecture wherein the quantum wells based on InGaN of the active region 22 extend transversely, parallel to the plane xy of the substrate 1. Such an axial architecture makes it possible in particular to incorporate a high concentration of indium (In) in the quantum wells of the active region 22. This axial architecture can therefore be used for manufacturing green or red 3D LEDs or micro-LEDs.

These so-called axial 3D structures are typically manufactured by molecular beam epitaxy (MBE) from a layer 11 of GaN. This growth technique makes it possible to obtain, unlike the other growth techniques conventionally used, a localised deposition of InGaN at the top of the wires based on GaN. Quantum wells based on InGaN can thus be formed parallel to the substrate. Axial 3D LEDs in the form of wires configured to emit in the green or in the red and each comprising a bottom part based on GaN, an active region based on InGaN disposed transversely to the wire, and a top region based on GaN, can thus be manufactured. The document US 2020279974 A1 describes in particular the manufacture, by MBE, of nanocolumns based on GaN having an axial architecture.

However, molecular beam epitaxy MBE is not a technique compatible with an industrial manufacturing method. Axial 3D LEDs showing good performances of emission in the green or in the red are therefore not viable on an industrial scale.

The present invention aims to at least partially overcome these drawbacks.

In particular, an object of the present invention is to propose an improved method for manufacturing a plurality of 3D structures for optoelectronics.

Another object of the present invention is to propose an optoelectronic device, in particular an axial 3D LED based on GaN, that can be manufactured in an optimised manner.

The other objects, features and advantages of the present invention will appear upon examining the following description and the accompanying drawings. It is understood that other advantages can be incorporated.

### SUMMARY OF THE INVENTION

To achieve the above-mentioned objectives, the present invention provides, according to a first aspect, a method for manufacturing a plurality of three-dimensional (3D) structures for optoelectronics, each 3D structure comprising, in a stack in a longitudinal direction z:
a bottom part comprising a base bearing on a substrate,
an active region configured to emit or receive light radiation, said active region bearing on a top, opposite to the base, of the bottom part, and
a top part bearing on a top of the active region, said method comprising:
Provision of a substrate carrying a plurality of bottom parts of 3D structures, said bottom parts having distinct tops such that the tops of two adjacent bottom parts are separated from each other by a separation distance ds of less than 180 nm, and preferably less than 100 nm.
Formation by metalorganic vapour-phase epitaxy (MOVPE) of the active regions on the tops of the bottom parts,
Formation of the top parts on the tops of the active regions.

The formation by metalorganic vapour-phase epitaxy (MOVPE) of the active regions advantageously makes it possible to make the method for manufacturing axial 3D LEDs industrially compatible.

According to a prejudged technique, it is generally accepted that MOVPE does not make it possible to form such axial 3D LEDs and that it is necessary to use MBE for manufacturing such structures.

Thus the known solutions based on MBE aim in particular to size the equipment for using MBE so that it is compatible with industrial production.

According to the prejudged technique mentioned above, growth by metalorganic vapour-phase epitaxy MOVPE produces substantially standard layers. Thus, according to this prejudging, an MOVPE deposition of InGaN on the bottom part of the 3D structure, for example a wire based on GaN, forms a continuous layer of InGaN on the sides and the top of the bottom part or of the wire, and the 3D structure obtained consequently has a so-called radial architecture.

On the other hand, in the context of the development of the present invention, it has appeared surprisingly that such an MOVPE deposition of InGaN on a set of 3D-structure bottom parts based on GaN close to each other makes it possible to obtain an axial 3D structure, where the material based on InGaN is located mainly on the top of the bottom parts.

According to one principle of the invention, the tops of the bottom parts are separated from each other by a separation distance ds of less than 180 nm. The periodic deposition of quantum wells of InGaN and of AlGaN barriers by MOVPE advantageously makes it possible to form the active regions on the tops of the bottom parts based on GaN. These active regions can have a truncated-pyramid shape at the top of the bottom parts, for example at the top of the wires.

These conditions of high density of bottom parts or of wires are favourable for the MOVPE advantageously to make it possible to obtain axial 3D structures. These conditions of high density are typically obtained for separation distances ds, between the adjacent tops of the bottom parts or of the wires, of less than or equal to 180 nm. Unlike the conventional range of separation distances disclosed by the document US 2020279974 A1 of between 1 nm and 500 nm, it has been observed in the context of the present invention that obtaining an axial architecture by MOVPE is possible only for a limited range of values, typically less than 180 nm and preferably between 20 nm and 180 nm. This unexpected effect, which is detailed hereinafter and in particular illustrated by the experimental points of FIG. 6, thus occur only in the range of values selected according to the principle of the invention. This method is compatible with the industrial manufacture of axial 3D LEDs.

Furthermore, the top active regions can have sufficient concentrations of indium, for example [In] ≥10% at, to form LEDs configured to emit light radiation in the green or in the red.

According to one possibility, the bottom parts are in the form of wires and are formed by MOVPE through openings in a masking layer. In this case, the openings in the masking layer are regularly distributed in the form of a lattice having a pitch of less than or equal to 700 nm. This pitch partly determines the separation distance ds between tops of the wires. At the end of the growth of the wires based on GaN, the latter are therefore relatively close to each other. This makes it possible to favour an axial growth of InGaN at the top of the wires, to form 3D structures in an axial architecture.

According to one possibility, the range of values of the separation distances making it possible to obtain an axial architecture by MOVPE depends on the ratio of surfaces, in a given zone, between the surface of the three-dimensional structures, in projection in a plane of the substrate, and the surface of the substrate. In other words, the range of values ds can depend on the ratio between the surface occupied by the 3D structures and the total surface, i.e. the coverage ratio of the substrate, or on the surface density of 3D structures. Thus the separation distance ds will preferably be selected according to a characteristic dimension Φ of the 3D structures, for example a diameter, so as to obtain a ratio of coverage of the substrate by the 3D structures greater than or equal to 0.6, and preferably greater than or equal to 0.8. A separation distance ds of less than or equal to one half of the characteristic dimension Φ, and preferably of less than or equal to one third of the characteristic dimension Φ, advantageously makes it possible to obtain an axial architecture by MOVPE.

A second aspect of the present invention relates to an optoelectronic device comprising a plurality of three-dimensional (3D) structures for optoelectronics, each 3D structure being in the form of a wire and comprising, in a so-called axial architecture:
a bottom part extending in a longitudinal direction and comprising a base bearing on a substrate,
an active region, preferably comprising at least one quantum well extending along a plane normal to the longitudinal direction, configured to emit or receive light radiation, where applicable from the at least one quantum well, said active region bearing on a top, opposite to the base, of the bottom part, and
a top part bearing on a top of the active region.

Advantageously, this device with an axial 3D structure furthermore comprises a masking layer in contact with a surface layer of the substrate. This masking layer advantageously comprises openings through which the bottom parts in the form of a wire extend. The bases of the bottom parts thus bear on the surface layer of the substrate.

Incorporating such a masking layer advantageously makes it possible to use MOVPE to form respectively the bottom part, active region and top part of the axial 3D structure. This masking layer can be preserved at the end of the manufacture of the 3D structures.

This masking layer furthermore mechanically reinforces the axial 3D structure obtained. It can be made from a dielectric material so as to electrically isolate the substrate with respect to a metal contact subsequently deposited on the top of the 3D structures for example. It can also be transparent so as to allow light radiation emitted or received by the 3D structures to pass. Advantageously, two tops of two adjacent bottom parts are separated from each other by a separation distance ds of less than 180 nm. This makes it possible in particular to obtain an axial 3D structure by MOVPE.

Naturally the features and advantages of one aspect of the invention can be transposed, mutatis mutandis, to another aspect of the invention.

### BRIEF DESCRIPTION OF THE FIGURES

The aims, objects, as well as the features and advantages of the invention will appear better from the detailed description of embodiments of the latter which are illustrated by the following appended drawings wherein:

FIG. 1 illustrates a 3D LED having a mesa structure according to the prior art.

FIG. 2 illustrates a 3D LED in the form of wires each having an axial architecture according to the prior art.

FIG. 3 illustrates a plurality of 3D structures in the form of wires each having an axial architecture according to an embodiment of the present invention.

FIG. 4 is a scanning transmission electron microscopy (STEM) image of 3D structures according to an embodiment of the present invention.

FIG. 5A is an enlarged view of the thumbnail a represented on the image in FIG. 4 showing quantum wells of a 3D structure according to an embodiment of the present invention.

FIG. 5B is an enlarged view of the thumbnail b represented on the image in FIG. 4 showing a side of a 3D structure according to an embodiment of the present invention.

FIG. 6 presents a curve showing various values of the ratio of the thicknesses deposited by MOVPE radially and axially on the wires, according to various separation distances ds between wires, according to an embodiment of the present invention.

FIG. 7 is a scanning electron microscopy (SEM) image of an optoelectronic device comprising a plurality of 3D structures according to an embodiment of the present invention.

FIG. 8 is a scanning transmission electron microscopy (STEM) image of a 3D structure according to an embodiment of the present invention.

FIG. 9 is an EDX map of a part of the image presented in FIG. 8, showing the distribution of indium at the top part of a 3D structure according to an embodiment of the present invention.

FIG. 10A is an EDX profile established according to the profile A represented on the image in FIG. 8 showing the presence of quantum wells at the top of a 3D structure according to an embodiment of the present invention.

FIG. 10B is an EDX profile established according to the profile B represented on the image in FIG. 8 showing the presence of quantum wells on a side of a 3D structure according to an embodiment of the present invention.

FIG. 11 is a scanning transmission electron microscopy (STEM) image of 3D structures according to an embodiment of the present invention.

FIG. 12A shows a scanning transmission electron microscopy (STEM) image of a detail of a 3D structure according to an embodiment of the present invention, and an EDX profile established according to the profile a represented on the STEM image.

FIG. 12B shows a scanning transmission electron microscopy (STEM) image of a detail of a 3D structure according to an embodiment of the present invention, and an EDX profile established according to the profile b represented on the STEM image.

FIG. 12C shows a scanning transmission electron microscopy (STEM) image of a detail of a 3D structure according to an embodiment of the present invention, and an EDX profile established according to the profile c represented on the STEM image.

FIGS. 13 to 16 illustrate various arrangements of 3D structures according to an embodiment of the present invention.

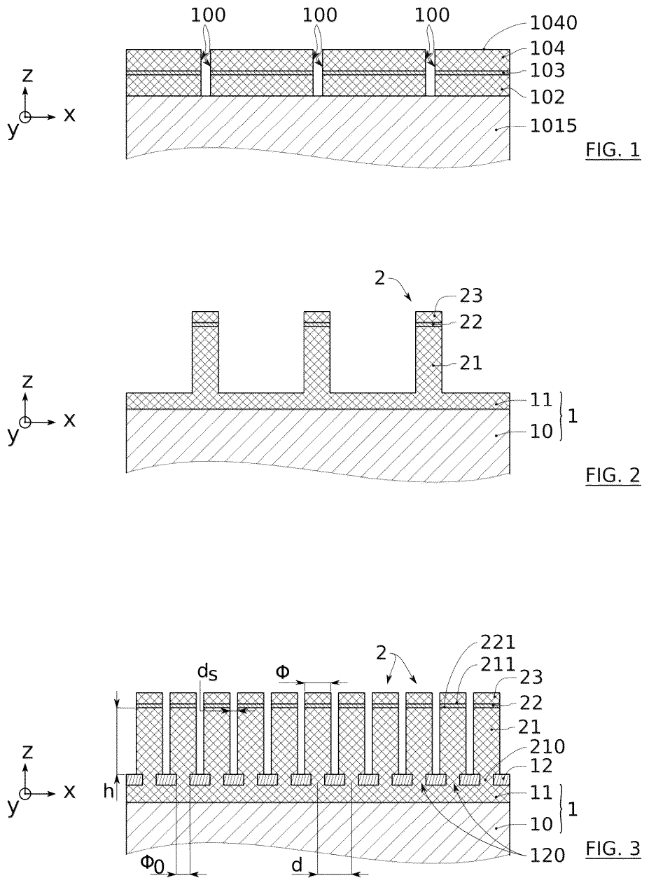

The drawings are provided by way of example and are not intended to limit the scope of the invention. They constitute diagrammatic views intended to ease the understanding of the invention and are not necessarily to the scale of practical applications. In particular, the dimensions of the different elements of the 3D structures are not necessarily representative of reality.

### DETAILED DESCRIPTION

Before starting a detailed review of embodiments of the invention, it should be recalled that the invention, according to the first aspect thereof, comprises in particular the optional features hereinafter which may be used in combination or alternatively.

According to one example, each 3D structure is in the form of a wire and comprises, in a so-called axial architecture:
a bottom part extending in a longitudinal direction and comprising a base bearing on a substrate,
an active region, comprising at least one quantum well extending along a plane normal to the longitudinal direction and configured to emit or receive light radiation from the at least one quantum well, said active region bearing on a top, opposite to the base, of the bottom part, and
a top part bearing on a top of the active region.

According to one example, the method comprises:
Provision of a substrate comprising at least one surface layer,
Formation of a masking layer on the substrate, said masking layer comprising openings through which zones of the surface layer are exposed,
Formation, from the exposed zones of the surface layer, bottom parts in the form of wires, the bases of said bottom parts bearing on the surface layer of the substrate, through the openings,
Formation by metalorganic vapour-phase epitaxy (MOVPE) of the active regions on the tops of the bottom parts,
Formation of the top parts on the tops of the active regions.

According to one example, the formation by MOVPE of the active regions comprises a so-called axial deposition taking place in the longitudinal direction and a so-called radial deposition taking place in a direction normal to the longitudinal direction, and a thickness of the radial deposition is less than or equal to 10% of a thickness of the axial deposition.

According to one example, the method is configured so that the bottom part has sides with no active region.

According to one example, the formation of the bottom parts is configured so that the tops of the bottom parts of the 3D structures are separated from each other by a separation distance ds of less than 180 nm, preferably less than 150 nm.

According to one example, the separation distance ds is less than or equal to 100 nm. According to one example, the bottom parts of the 3D structures are distributed within the plurality so as to have a surface density greater than or equal to 4 μm⁻².

According to one example, the formation of the masking layer is configured so that the openings in the masking layer are spaced apart by a distance d of less than 700 nm.

According to one example, the formation of the masking layer is configured so that the openings in the masking layer are distributed so as to have a surface density greater than or equal to 4 μm⁻².

According to one example, the tops of the bottom parts have a characteristic dimension Φ, such as a diameter, taken in a plane normal to the longitudinal direction z and lying between 30 nm and 550 nm, preferably between 50 nm and 500 nm.

According to one example, the separation distance ds and the characteristic dimension Φ are selected so that Φ/(Φ+ds)≥0.6, and preferably Φ/(Φ+ds)≥0.8.

According to one example, the 3D structures occupy a surface S2 on a delimited zone of the substrate of surface S1, said surfaces S1, S2 being selected so that S2/S1≥0.8, and the characteristic dimension Φ is selected so that 90 nm 500 nm, preferably so that 150 nm≤500 nm.

According to one example, the 3D structures occupy a surface S2 on a delimited zone of the substrate of surface S1, said surfaces S1, S2 being selected so that S2/S1≥0.6, and the characteristic dimension Φ is selected so that Φ≤100 nm.

According to one example, the 3D structures occupy a surface S2 on a delimited zone of the substrate of surface S1, said surfaces S1, S2 being selected so that S2/S1≥0.7, and the characteristic dimension Φ is selected so that Φ≤200 nm.

According to one example,

$${( \frac{Φ}{Φ + ds} )}^{2} = \frac{{S}_{2}}{{S}_{1}} .$$

According to one example, the method is configured so that the active region extends solely from the top of the bottom part.

According to one example, the bottom parts and the top parts are selected so as to be based on GaN and the active region is selected so as to be based on InGaN.

According to one example, the active region comprises at least one quantum well based on InGaN.

According to one example, the active region comprises a layer of InGaN with a thickness greater than 5 nm.

According to one example, the active region comprises a set of quantum dots based on InGaN.

According to one example, the at least one quantum well based on InGaN is formed by MOVPE at a temperature greater than or equal to 700° C.

According to one example, the active region extends transversely to the longitudinal direction z. According to one example, the surface layer has a thickness of between 50 nm and 200 nm. According to one example, the 3D structures are entirely formed by metalorganic vapour phase epitaxy (MOVPE).

According to one example, the openings in the masking layer are regularly spaced apart by a pitch of less than or equal to 700 nm.

According to one example, the formation of the active region is configured so that the quantum wells based on InGaN have a proportion of indium [In] 10% at.

The invention, according to the second aspect thereof, comprises in particular the optional features hereinafter which may be used in combination or alternatively:

According to one example, the principal wavelength A of the light radiation is greater than or equal to 400 nm and/or is less than or equal to 700 nm.

According to one example, the principal wavelength A of the light radiation is between 500 nm and 650 nm.

According to one example, the bottom part of the wire has a height greater than or equal to 150 nm.

According to one example, the bottom part of the wire has a diameter greater than or equal to 30 nm and/or less than or equal to 500 nm.

According to one example, the tops of the bottom parts of the 3D structures are separated from each other by a separation distance ds of less than or equal to 100 nm.

According to one example, the bases have a diameter less than a diameter of the tops of the bottom parts, certainly at least 10% less.

According to one example, the bottom parts have a cross-section increasing abruptly between a zone included in the openings and a zone located outside the openings.

According to one example, preferably for each 3D structure, the active region extends solely from the top of the bottom part.

According to one example, the tops of the bottom parts have a characteristic dimension Φ, such as a diameter, taken in a plane normal to the longitudinal direction z and lying between 30 nanometres and 550 nanometres, preferably between 50 nm and 500 nanometres.

According to one example, preferably for each 3D structure, the active region has a truncated pyramidal shape.

According to one example, preferably for each 3D structure, the active region in the form of a truncated pyramid comprises faces inclined by an angle of approximately 30° with respect to the longitudinal direction, these inclined faces corresponding substantially to semipolar planes of the {10-11} type.

According to one example, preferably for each 3D structure, the top of the bottom part of the wire is surrounded by a collar.

According to one example, preferably for each 3D structure, the collar has continuity with the inclined faces of the truncated pyramid forming the active region.

According to one example, the quantum wells based on InGaN have a proportion of indium [In] 10%.

Except in the case of incompatibility, it is understood that the manufacturing method and the optoelectronic device may comprise, mutatis mutandis, any one of the following optional features. In the present invention, the method for manufacturing axial 3D structures is in particular dedicated to manufacturing 3D LEDs.

More generally, the invention may be implemented more broadly for various optoelectronic devices with a 3D structure, and in particular those comprising active regions.

Active region of a 3D structure of an optoelectronic device means the region from which the majority of the light radiation provided by this structure is emitted, or the region from which the majority of the light radiation received by this structure is captured.

The invention may therefore also be implemented in the context of laser or photovoltaic devices. Unless stated explicitly, it is specified that, in the context of the present invention, the relative arrangement of a third layer interposed between a first layer and a second layer does not necessarily mean that the layers are directly in contact with each other, but means that the third layer is either directly in contact with the first and second layers, or separated from these by at least one other layer or at least one other element.

The steps of forming the various elements mean in the broad sense: they can be implemented in several sub-steps that are not necessarily strictly successive.

Diameter means the largest transverse dimension at the relevant point of the 3D structure (for example diameter of the base of the bottom part, diameter of the top of the bottom part, diameter of the collar, diameter of the top of the truncated pyramid). In the present invention, the 3D structures do not necessarily have a circular cross-section. In particular, in the case of 3D structures based on GaN, this cross-section may be hexagonal. The diameter then corresponds to the distance separating two opposite vertices of the hexagonal cross-section. Alternatively, the diameter may correspond to a mean diameter calculated from the diameter of a circle inscribed in the polygon of the cross section and from the diameter of a circumscribed circle of this polygon.

The 3D structures may have a hexagonal or polygonal cross-section. The active regions in the form of truncated pyramids bear on an end of the bottom parts of the 3D structures. The truncated pyramids preferably have the same hexagonal or polygonal base as these bottom parts. Wire means a 3D structure of with a form elongate in the longitudinal direction. The longitudinal dimension of the wire, along z in the figures, is larger, and preferably very much larger, than the transverse dimensions of the wire, in the plane xy in the figures. For example, the longitudinal dimension is at least five times, and preferably at least ten times, larger than the transverse dimensions.

The surface density of the 3D structures depends on the separation distance ds separating the tops of the bottom parts of two adjacent 3D structures. It may in particular be inversely proportional to this distance ds along k/ds 2 with k a proportionality factor. This density is expressed in μm⁻², i.e. as number of 3D structures per square micrometre.

In the present patent application, the terms “concentration”, “proportion” and “content” are synonymous.

More particularly, a concentration may be expressed in a relative unit such as molar or atomic fractions (% at), or in an absolute unit such as the number of atoms per cubic centimetre (at·cm⁻³).

Hereinafter, the concentrations are atomic fractions expressed as % at, unless mentioned to the contrary.

In the present patent application, the terms “light-emitting diode”, “LED” or simply “diode” are used as synonyms. An “LED” may also be understood as a “micro-LED”.

Hereinafter, the following abbreviations relating to a material M are optionally used:
M-i refers to the material M, intrinsic or not, intentionally doped, according to the terminology normally used in the field of microelectronics for the suffix -i.
M-n refers to the n, n+ or n++ doped material M, according to the terminology normally used in the field of microelectronics for the suffix -n.
M-p refers to the p, p+ or p++ doped material M, according to the terminology normally used in the field of microelectronics for the
suffix -p.

A substrate, a layer or a device, “based” on a material M means a substrate, a layer or a device comprising this material M alone or this material M and possibly other materials, for example, alloy elements, impurities or doping elements. Thus a 3D structure based on gallium nitride (GaN) may for example comprise gallium nitride (GaN or GaN-i) or doped gallium nitride (GaN-p, GaN-n). An active region based on indium gallium nitride (InGaN) may for example comprise aluminium gallium nitride (AlGaN) or gallium nitride with various proportions of aluminium and indium (GaInAlN). In the context of the present invention, the material M is generally crystalline. A reference frame, preferably orthonormal, comprising the axes x, y, z is represented in the appended figures.

In the present patent application, we will preferably talk about thickness for a layer and height for a structure or a device. The thickness is considered according to a direction normal to the main plane of extension of the layer, and the height is considered perpendicularly to the base plane xy of the substrate. Thus a surface layer typically has a thickness along z, and a wire has a height along z. A thickness of an axial deposit is taken along z and a thickness of a radial deposit is taken in the plane xy.

The dimensional values should be understood within manufacturing and measurement tolerances. Thus two identical separation distances ds or two diameters of wires that are identical in theory may have a slight dimensional variation in practice.

The terms “substantially”, “about”, “in the range of” mean, when they relate to a value, “within 10%” of this value or, when they relate to an angular orientation, “within 10°” of this orientation. Thus a direction substantially normal to a plane means a direction having an angle of 90±10° with respect to the plane.

To determine the geometry of the 3D structures and the compositions of the various elements (wire, active region, collar for example) of these 3D structures, scanning electron microscopy (SEM) or transmission electron microscopy (TEM) or scanning transmission electron microscopy STEM analyses can be carried out.

TEM or STEM lend themselves particularly well to observing and identifying quantum wells—the thickness of which is generally of the order of a few nanometres—in the active region. Various techniques listed below non-exhaustively can be used: dark field, bright field, weak beam and high angle annular dark field (HAADF) diffraction imaging.

The chemical compositions of the various elements can be determined using the well-known method EDX or X-EDS, the acronym of “energy dispersive X-ray spectroscopy”.

This method is well adapted for analysing the composition of small optoelectronic devices such as 3D LEDs. It can be used on metallurgical sections in scanning electron microscopy (SEM) or on thin slices in a transmission electron microscope (TEM).

The optical properties of the various elements, and in particular the principal emission wavelengths of axial 3D LEDs based on GaN and/or of the active regions based on InGaN, can be determined by spectroscopy.

Cathodoluminescence (CL) or photoluminescence (PL) spectroscopies are well adapted for optically characterising the 3D structures described in the present invention.

The techniques mentioned above make it possible in particular to determine whether an optoelectronic device with axial 3D structure in the form of a wire comprises quantum wells based on InGaN formed at the top of a wire based on GaN, and a masking layer indicating use of a deposit of the MOVPE type, as described in the present invention. The optional presence of a collar is also easily observable by means of these techniques.

The method according to the invention can be implemented according to two main approaches. A first approach consists in forming the bottom parts of the 3D structures, the active regions and preferably the top parts, directly by successive growths, preferably by successive MOVPE growths. This first approach is said to be “bottom-up” according to the terminology generally used, since the 3D structures are formed from bottom to top.

A second approach consists in forming the bottom parts of the 3D structures from a pre-existing 2D layer, by etching this 2D layer. The active regions and preferably the top parts are next formed by successive growths, preferably by successive MOVPE growths. This second approach is said to be “top-down” according to the terminology generally used, since the bottom parts of the 3D structures are formed from top to bottom.

The following examples are in the context of the “bottom-up” approach.

A first example of implementing 3D structures according to the invention will now be described with reference to FIGS. 3, 4 and 5A, 5B.

FIG. 3 illustrates a plurality of adjacent 3D structures 2 distributed on the same substrate 1. The following description relating to one of these 3D structures naturally extends to the other 3D structures in this plurality, which are deemed to be substantially identical to each other.

The 3D structure 2 comprises at least one bottom part 21 in the form of a wire and an active region 22 at the top of this bottom part 21. It is preferably formed directly from the substrate 1. This substrate 1 can be in the form of a stack comprising, in the direction z, a support 10, a surface layer 11 referred to as a nucleation layer, and a masking layer 12. The substrate 1 is substantially planar and parallel to the plane xy.

In particular, the substrate 10 may be made of sapphire to limit the mesh parameter discrepancy with GaN, or of silicon to reduce costs and for technological compatibility problems. In the latter case, it might be in the form of a wafer with a diameter of 200 mm or 300 mm. In particular, it serves as a support to the 3D structures.

Preferably, the nucleation layer 11 is based on AlN. Alternatively, it may be based on metal nitrides, for example GaN or AlGaN. It may be formed on the silicone support 10 by epitaxy, preferably by MetalOrganic Vapour Phase Epitaxy MOVPE. According to one example, the nucleation layer 11 has a thickness of between 1 nm and 10 nm. It preferably has a thickness of the order of a few hundreds of nanometres, for example approximately 100 nm or 200 nm, to a few microns, example of the order of 2 μm. This may also have a thickness of less than 100 nm. This allows limiting the mechanical stresses induced by this layer 11 on the substrate 10. This allows avoiding a detrimental curvature of the substrate 10. Such a thickness further allows limiting the apparition of structural defects in the nucleation layer 11. In particular, the growth of this nucleation layer 11 may be pseudomorphic, i.e. the epitaxy stresses (related in particular to the difference in mesh parameters between Si and AlN, GaN or AlGaN) may be elastically relieved during the growth. Thus the crystalline quality of this nucleation layer 11 may be optimised. Preferably, the masking layer 12 is made of a dielectric material, for example of silicon nitride Si₃N₄. It can be deposited by Chemical-Vapour Deposition CVD over the nucleation layer 11. It partially masks the nucleation layer 11 and comprises openings 120, preferably circular, exposing zones of the nucleation layer 11. Typically, these openings 120 have a dimension, for example a diameter Φₒ or an average diameter, lying between 30 nm and 500 μm. The openings 120 may be evenly distributed within the masking layer 12, for example in the form of an ordered array.

The pitch d, i.e. the distance separating the centres of two adjacent openings 120, is preferably smaller than or equal to 700 nm. It may be between 50 nm and 650 nm. Advantageously, the openings 120 have a surface density higher than 4 μm⁻². Ultimately, this allows obtaining 3D structures densely distributed over the substrate 1. For example, these openings 120 may be made by UV or DUV (acronym of Deep UV) lithography, by electron beam lithography, or by NIL (acronym of NanoInprint Lithography). Such a masking layer 12 allows for a localised growth of a 3D structure at each opening 120. In particular, during a preliminary growth step called germination, a GaN-based seed is formed at the opening 120 and then fills said opening 120. The subsequent growth of the bottom part of the 3D structure is then done starting from this seed, in a localised manner. This seed thus forms the base 210 of the bottom part 21 of the 3D structure. The bottom part 21 bears on the nucleation layer 11 of the substrate 1 by means of its base 210. The bottom part 21 of the 3D structure is preferably based on GaN, in particular based on GaN-n. It is preferably oriented parallel to z in a crystallographic direction corresponding to the axis c of a hexagonal crystallographic structure.

The formation of this bottom part 21 based on GaN may be done by epitaxy, preferably by MetalOrganic Vapour Phase Epitaxy MOVPE, in particular as defined in the publication WO 2012/136665. Typically, the source of gallium in the form of an organometallic precursor (precursor III) may be trimethyl-gallium (TMGa) or triethyl-gallium (TEGa). Typically, the source of nitrogen may be ammonium hydroxide (NH₃) or nitrogen (N₂) (precursor V). The growth temperature is preferably above 700° C., for example of the order of 1000° C. The gas pressure in the growth reactor is for example of the order of 425 torr. The growth is preferably done under neutral and/or reducing atmosphere, typically by adding nitrogen N₂ and/or dihydrogen H₂. The flows of the different gases may be adapted in a manner known to a person skilled in the art, in particular according to the volume of the reactor.

Alternatively, the formation of the bottom part 21 may be done by Hydride Vapour Phase Epitaxy HVPE, by Chemical-Vapour Deposition CVD and MOCVD (the acronym of MetalOrganic Chemical-Vapour Deposition).

Optionally, conventional steps of preparing the surface of the seed 210 (chemical cleaning, heat treatment) may be performed prior to the epitaxial growth of the bottom part 21.

The bottom part 21 of the 3D structure 2 may comprise a region based on n-doped GaN (GaN-n). In a known manner, this n-doped region may result from a growth, an implantation and/or an activation annealing. In particular, the n doping may be obtained directly during the growth, starting from a silicon or germanium source, for example by addition of silane or disilane or germanium vapour. The growth conditions required for the formation of such a bottom part 21 are widely known.

The bottom part 21 of the 3D structure 2 preferably has a diameter greater than or equal to 30 nm and/or less than or equal to 550 nm and/or less than or equal to 500 nm. The cross-section of the bottom part 21, in the plane xy, may typically have a more or less regular hexagonal shape. The diameter Φ may in this case be a mean diameter. The diameter Φ may be greater than the diameter Φₒ of the opening 120 and of the base 210 that gave rise to the bottom part 21. The cross-section may thus have an abrupt variation in diameter between its base 210 included in the opening 120 and its main part outside the opening 120, referred to as the main bottom part 21. The base 210 of the bottom part 21 of the 3D structure 2 is gripped by the masking layer 12. The main bottom part 21 may furthermore bear on the masking layer 12. This thus mechanically reinforces the 3D structure 2. This mechanical reinforcement is all the greater as the aspect ratio of the 3D structure increases.

The main bottom part 21 in particular has a height h greater than or equal to 100 nm, preferably greater than or equal to 200 nm. The main bottom part 21 preferably has an aspect ratio h/Φ greater than 1, and preferably greater than 5. This improves the crystalline quality at the top 211 of this bottom part 21. This also distances the top 211 from the underlying planar substrate 1. The local environment at the top 211 is thus not disturbed by the underlying planar substrate 1. The top 211 of the bottom part 21 is preferably substantially planar and parallel to the plane xy, so as to accommodate the active region 22.

In the case of an LED, the active region 22 may typically comprise a plurality of quantum wells configured to send light radiation at a principal wavelength A. These quantum wells are for example based on InGaN. They may conventionally be separated from each other by barriers based on AlGaN.

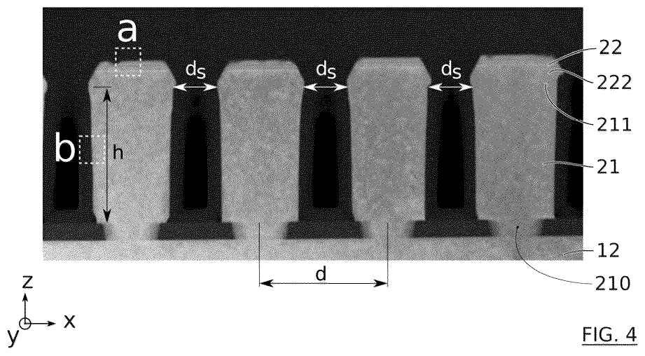

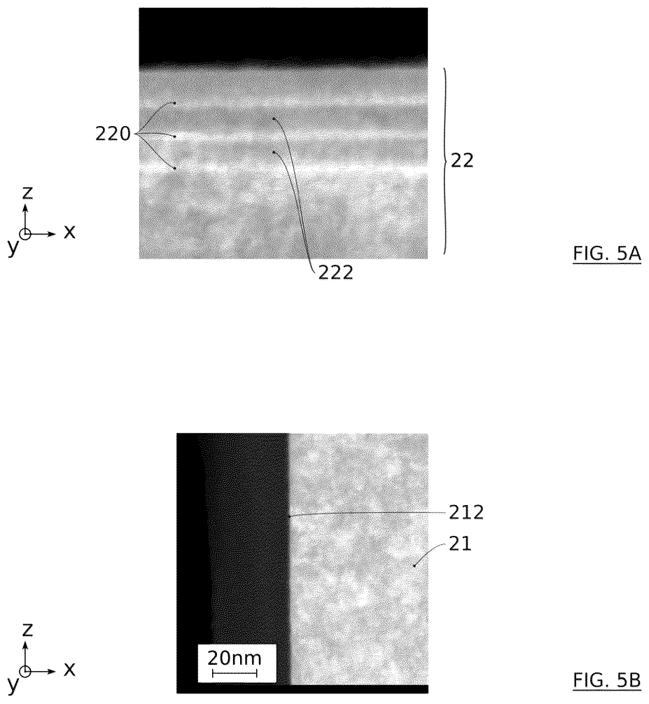

The active region 22 is preferably oriented in the same crystallographic direction as the bottom part 21. In the example illustrated by FIGS. 4, 5A and 5B, it comprises in particular the quantum wells 220 based on InGaN visible on the STEM HAADF image in FIG. 4, and more particularly on the STEM HAADF image in FIG. 5A, which is an enlargement of the zone marked a in FIG. 4. The active region 22 may comprise at least one quantum well 220. The number of quantum wells 220 of the active region 22 may be between 1 and 20. The quantum wells 220 preferably extend along planes xy and typically separated along z by quantum barriers 222 (FIG. 5A). Alternatively, the active region 22 may be in the form of a layer based on InGaN with a thickness greater than or equal to 5 nm, for example 30 nm. Alternatively, the active region 22 may comprise a set of quantum dots based on InGaN.

The formation of this active region 22 is preferably done by metalorganic vapour-phase epitaxy MOVPE. This includes in particular the techniques of epitaxy by CVD, such as HVPE epitaxy. The growth conditions required for the formation of the active region 22 differ from those required for the formation of the bottom part 21. A source of indium in the form of organometallic precursor, for example trimethyl-indium (TMIn) or triethyl-indium (TEIn), is in particular added to the sources of gallium (TEGa) and/or trimethyl-gallium (TMGa) and of nitrogen (NH₃) to grow the quantum wells 220 based on InGaN. The ratio of the precursor element of indium (TMIn, TEIn) to all the precursors III (TEGa, TMGa and TMIn etc.) can be of the order of 0.3. The growth temperature may be of the order of 800° C. The gas pressure in the growth reactor is for example of the order of 100 torr. The V/III or In/III ratio, the pressure and the growth temperature can be adjusted according to the design of the epitaxy reactor and the emission wavelength sought. The formation of the bottom part 21 and the formation of the active region 22 can advantageously be done in one of the same reactor or growth frame.

The immediate environment at the top 211 of the bottom part 21 may influence the growth morphology. In particular, the proximity of other adjacent tops 211 may locally modify the growth conditions of the active region 22, and in particular of the quantum wells 220 based on InGaN. In the context of the development of the present invention, it has appeared that a density of bottom parts 21 in the form of elevated wires, in particular greater than 4 μm⁻², favours the growth of the quantum wells 220 along planes xy. Thus the active region 22 formed by MOVPE is confined to the top 211 of the bottom part 21 of the 3D structure. The sides 212 of the bottom part 21 can thus be at least partly devoid of active region 22, in particular of quantum wells based on InGaN, as shown by the STEM HAADF image in FIG. 5B. An axial 3D structure is thus obtained by MOVPE.

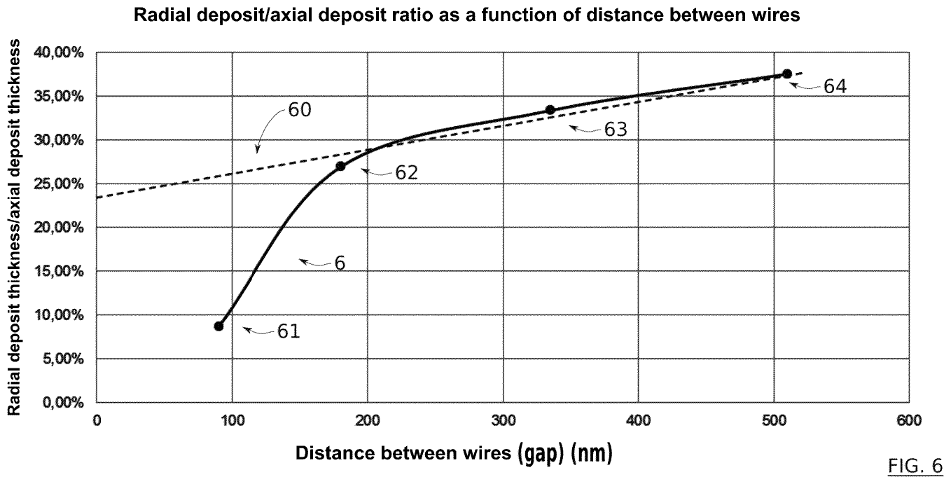

The distance ds between the tops 211 of two adjacent bottom parts 21 is a parameter influencing the morphology of the MOVPE deposition making it possible to form the active regions 22. The distance ds typically corresponds to the minimum separation between the borders of the tops 211 of the two adjacent bottom parts 21 concerned. In particular, this MOVPE deposit may comprise a proportion of axial deposit, i.e. along z, and a proportion of radial deposit, i.e. in a direction normal to z. These proportions vary according to the distance ds, as illustrated in FIG. 6. This FIG. 6 shows that the experimental curve 6 tracing the ratio of the thicknesses of radial to axial deposit decreases abruptly, unexpectedly, for distances ds of less than or equal to 200 nm, more particularly less than or equal to 180 nm. In particular, for a distance ds of less than 100 nm, of the order of 90 nm, the experimental point 61 corresponds to a ratio of radial to axial deposit thicknesses of less than 10%. Axial deposit means an increase in thickness along z; radial deposit means an increase in thickness in a direction perpendicular to the previous one, in particular at the sides of the projecting elements on the substrate. The deposit is thus in the great majority axial for this distance ds between tops 211 of the order of 90 nm. This behaviour deviates from the expected linear behaviour shown by the curve 60 extrapolated from the experimental points 62, 63, 64. The proximity of the tops 211 of the bottom parts 21 of the 3D structures clearly and surprisingly favours an axial growth of the active regions 22. A separation distance ds of greater than or equal to 20 nm will preferably be selected, in order to avoid or to limit the occurrence of defects during the formation of the 3D structures. This improves the quality and the homogeneity of the 3D structures formed. In practice, a separation distance ds of less than 10 nm is difficult to achieve. In practice, a separation distance ds of the order of 1 nm is impossible to achieve. Another parameter that may influence the morphology of the MOVPE deposit is the surface density or the coverage rate of the 3D structures. In the limit of maximum separation distance mentioned above, ds≤180 nm, it was also observed that it was advantageous to select a coverage rate greater than or equal to 0.6 in order to favour the axial growth of the active region at the top of the bottom parts of the wires. This may also result in a condition between the separation distance ds and the characteristic dimension Φ. Typically, ds<Φ, preferably ds≤3.Φ/4, and preferably ds≤Φ/2, will be selected. On FIG. 6, the experimental point 61, corresponding to an axial MOVPE growth, was obtained for ds=90 nm and Φ=180 nm, i.e. ds/Φ=0.5. The experimental point 62, corresponding to an MOVPE growth that can be considered to be the limit of an axial growth, was obtained for ds=180 nm and =210 nm, i.e. ds/Φ=0.85. The experimental point 63, corresponding to a significantly radial, non-axial, MOVPE growth, was obtained for ds=340 nm and Φ=260 nm, i.e. ds/Φ=1.3.

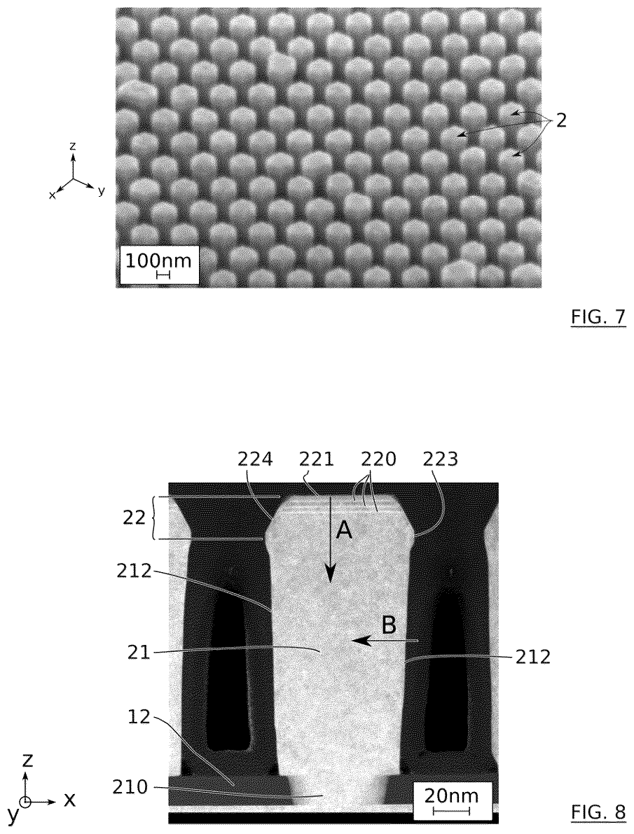

FIGS. 7 and 8 are other electron microscopy images of these axial 3D structures 2 obtained by MOVPE.

FIG. 7 is an SEM image showing dense 3D structures 2, regularly arranged on a substrate 1 (not visible) by means of a masking layer (not visible). In this example, the 3D structures have a diameter of approximately 200 nm (for an opening diameter of 50 nm) and a surface density of the order of 10 μm⁻².

FIG. 8 is an STEM HAADF image of an axial 3D structure from the plurality of 3D structures illustrated in FIG. 7, seen in cross section. The base 210 encased in an opening in the masking layer 12, the main bottom part 21 and the active region 22 comprising 3 quantum wells 220 are clearly visible.

The active region 22 bears on the top 211 of the bottom part 21 and has a top 221 able to receive a top part 23 (not present on the 3D structure of FIG. 8). The active region 22 may typically have the shape of a truncated pyramid (FIG. 8). This truncated pyramid may typically have a cross-section, in the plane xy, with a more or less regular hexagonal shape. The active region 22 in the form of a truncated pyramid thus comprises inclined sides or faces 224 extending from the top 211 of the bottom part 21 as far as the top 221. In particular, these faces 224 may be six in number. These faces 224 may be inclined by something of the order of 60° with respect to the plane xy. Such faces 224 may in particular correspond to planes of the type {10-11}. According to another possibility, the faces 224 may be inclined by an angle of approximately 80° with respect to the plane xy. Such an inclination of the faces 224 coincides approximately with semi-polar planes of the type {20-21}.

The active region 22 in the form of a truncated pyramid may be extended under the top 211 of the bottom part 21, in the form of a collar 223 for example (FIG. 8). This collar 223 may comprise facets extending the faces 224 of the active region 22. This collar 223 typically forms, with the part of the active region 22 in a truncated pyramid, a cap covering the top 211 of the bottom part 21. The collar 223 makes it possible for example to improve the mechanical cohesion between the bottom part 21 and the active region 22. The collar 223 may have a significant height, of the order of one third or one half of the height of the truncated pyramid for example. It may also be extended towards the base 210 of the bottom part 21, in the form of a thin layer of a few nanometres, example of the order of 1 to 5 nm, covering the sides 212 of the bottom part 21. The collar 223 is not necessarily continuous with the truncated pyramid of the active region 22. It may be independent of it.

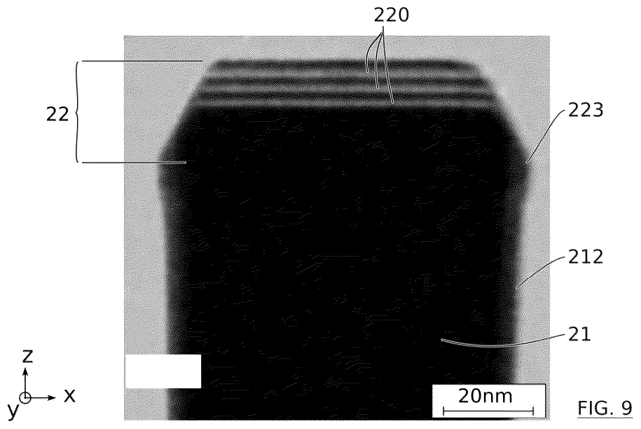

The distribution of indium in the active region 22 is located at the quantum wells 220, as shown by the EDX map of the element indium presented in FIG. 9. The incorporation of indium at the collar 223 and sides 212 of the bottom part 21 is small or even zero (FIG. 9). The quantum wells 220 formed by MOVPE here extend solely along the planes xy. The architecture obtained is clearly axial. The quantum wells 220 do not follow the faces 224.

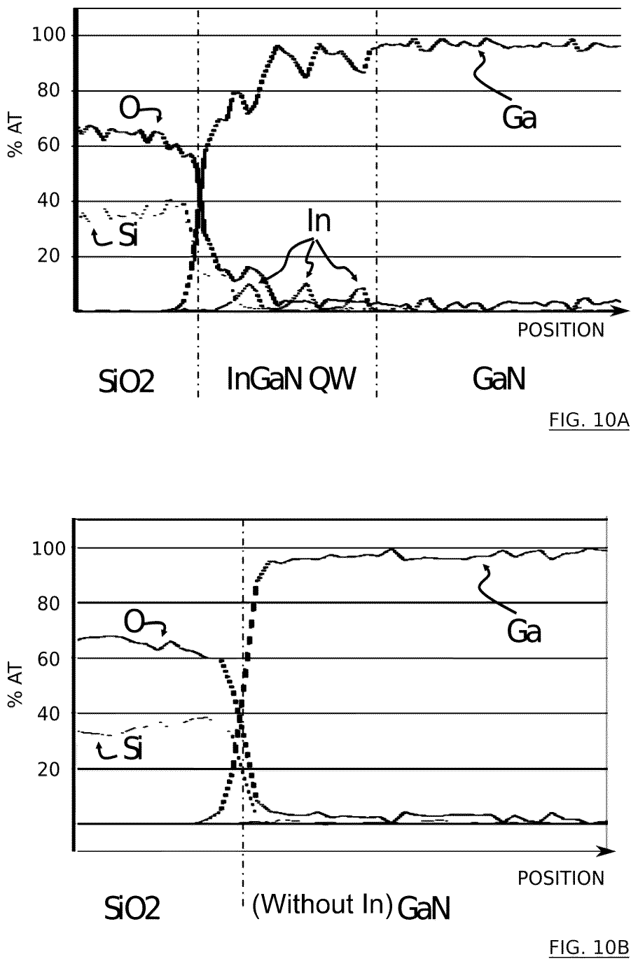

FIGS. 10A and 10B confirm this distribution of indium in the axial 3D structure grown by MOVPE. FIG. 10A presents an EDX profile acquired at the active region 22, along the profile A displayed on FIG. 8. This profile makes it possible to obtain the atomic fractions (% at) of the various chemical elements (O, Si, In, Ga) present in the profile acquisition zone. On FIG. 10A, the first part “SiO₂” of the profile corresponds to the silicon dioxide protective layer deposited on the top 221 of the 3D structure during the preparation of a sample observable by STEM. The second part “InGaN QW” of the profile corresponds to the active region 22 of the 3D structure. Three indium peaks corresponding to three quantum wells of InGaN in this active region 22 are clearly detected. The third part “GaN” of the profile corresponds to the bottom part 21 of the 3D structure, under the top 211. The presence of indium is not detected. Indium has therefore not diffused in the bottom part 21.

FIG. 10B presents an EDX profile acquired at a side 212 of the bottom part 21, along the profile B displayed on FIG. 8. This profile makes it possible to obtain the atomic fractions (% at) of the various chemical elements present in the profile acquisition zone. On FIG. 10B, the first part “SiO₂” of the profile corresponds to the silicon dioxide protective layer deposited on the sides 212 of the 3D structure during the preparation of a sample observable by STEM. The second part “In-free GaN” of the profile corresponds to the bottom part 21 of the 3D structure, at a side 212. The presence of indium is not detected. Indium has therefore not diffused on the sides 212 of the bottom part 21. The 3D structure obtained by MOVPE thus clearly has an axial architecture.

In the case of an optoelectronic device, for example an LED, the active region 22 is typically surmounted by a top part 23 based on GaN, in particular based on p-doped GaN. This top part 23 typically covers the active region 22 and makes it possible to inject carriers into the active region 22. The growth of the top part 23 on the active region 22 is preferably done by MOVPE. The thickness of the deposit for forming this top part 23 is preferably limited to a few tens of nanometres, for example less than 100 nm, or even less than 50 nm, so as to limit resorption of the light radiation emitted by the active region 22.

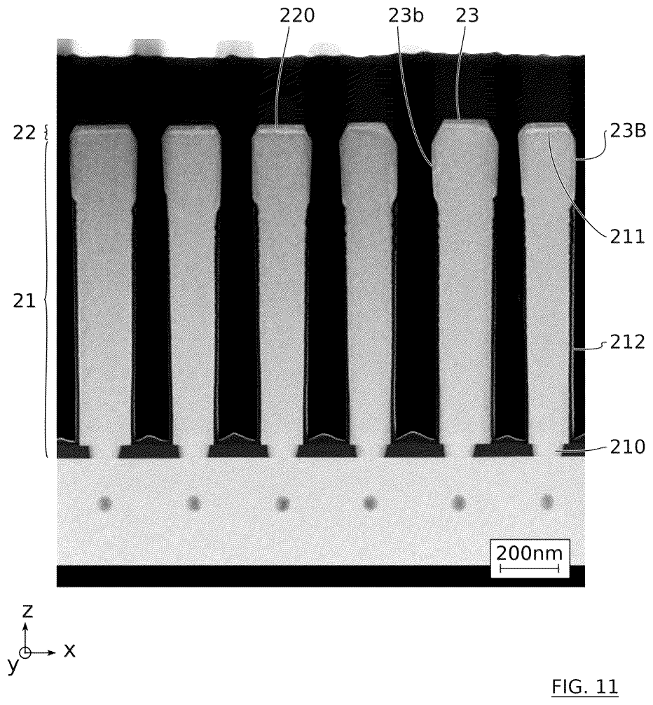

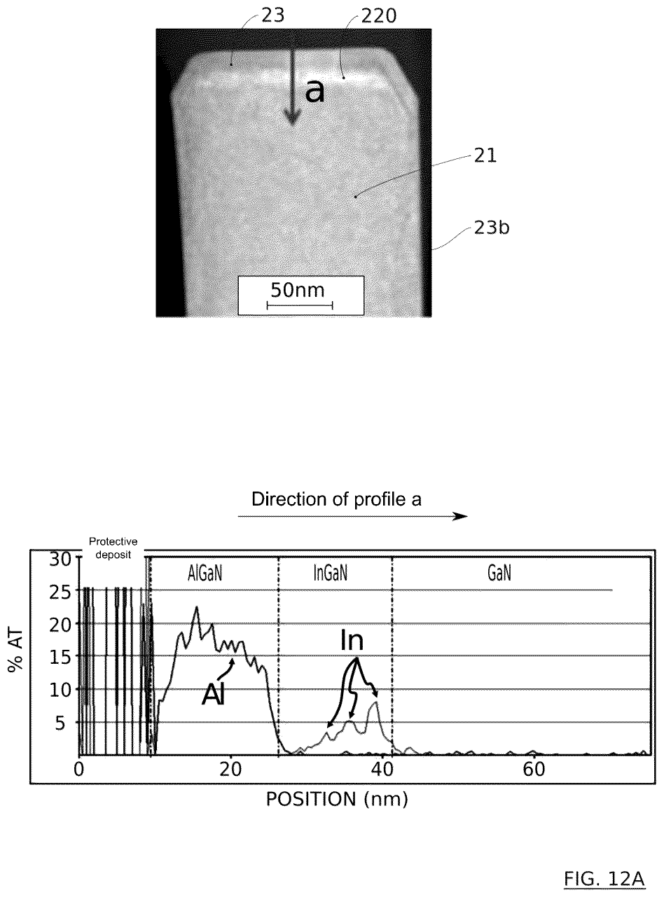

FIG. 11 illustrates axial 3D structures grown by MOVPE each comprising a bottom part 21, an active region 22 and a top part 23, 23b.

This top part 23 may extend solely over the top 221 of the active region 22. Alternatively, the top part 23, 23b extends partly over the top 221 of the active region 22 and partly over the sides of the active region 22 and over the sides 212 of the bottom part 21 under the top 211, as illustrated in FIG. 11.

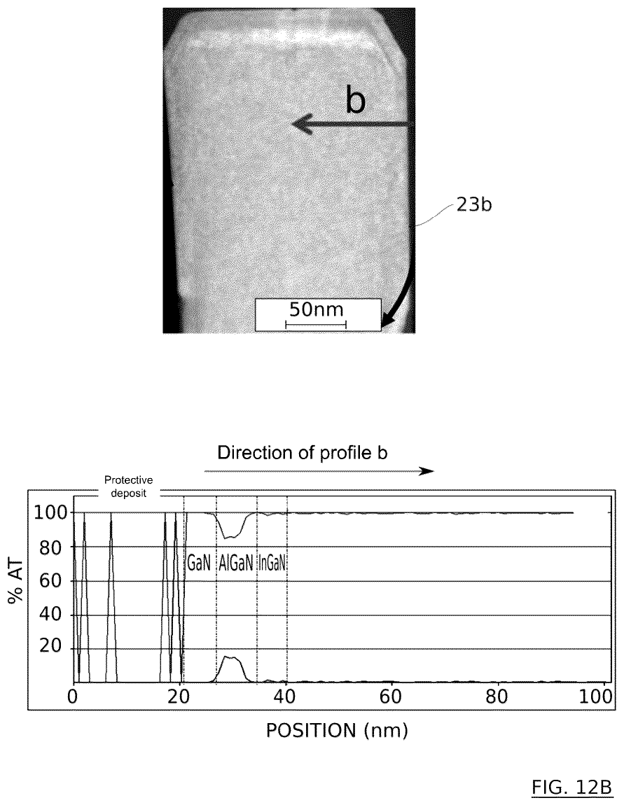

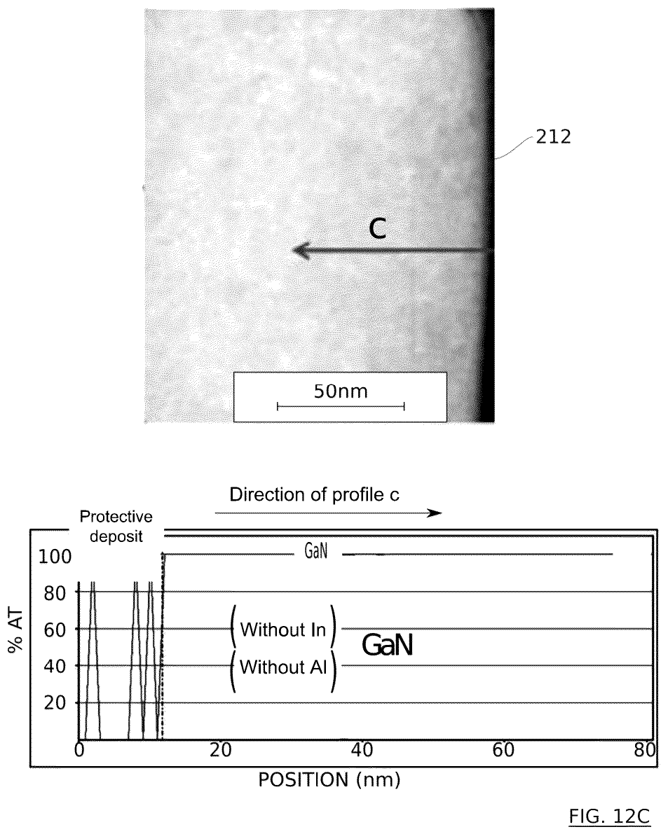

FIGS. 12A, 12B and 12C have various EDX profiles acquired on the axial 3D structures illustrated in FIG. 11.

FIG. 12A presents a STEM image of a 3D structure and an EDX profile acquired along the profile a represented on said STEM image, through the top part 23 and the active region 22 of the 3D structure. This profile makes it possible to obtain the atomic fractions (% at) of the various chemical elements present in the profile acquisition zone. On FIG. 12A, the first “protective deposit” part of the profile corresponds to the protective layer deposited around the 3D structure when a sample observable by STEM is prepared. The second part “AlGaN” of the profile corresponds to the top part 23 of the 3D structure. The third part “InGaN” of the profile corresponds to the active region 22 of the 3D structure. The fourth part “GaN” of the profile corresponds to the bottom part 21 of the 3D structure, under the top 211.

FIG. 12B presents a STEM image of a 3D structure and an EDX profile acquired along the profile b represented on said STEM image, through the top part 23b of the 3D structure. This profile makes it possible to obtain the atomic fractions (% at) of the various chemical elements present in the profile acquisition zone. On FIG. 12B, the “protective deposit” part of the profile corresponds to the protective layer deposited around the 3D structure when a sample observable by STEM is prepared. The parts “GaN” and “AlGaN” of the profile correspond to the top part 23b of the 3D structure. The “InGaN” part of the profile corresponds to the detection of traces of indium between the top part 23b and the bottom part 21 of the 3D structure. The “GaN” part of the profile corresponds to the bottom part 21 of the 3D structure, under the top 211.

FIG. 12C presents a STEM image of a 3D structure and an EDX profile acquired along the profile c represented on said STEM image, through a side 212 of the bottom part 21 of the 3D structure. This profile makes it possible to obtain the atomic fractions (% at) of the various chemical elements present in the profile acquisition zone. On FIG. 12C, the “protective deposit” part of the profile corresponds to the protective layer deposited around the 3D structure during the preparation of a sample observable by STEM. The “GaN (In-free) (Al-free)” part of the profile corresponds to the bottom part 21 of the 3D structure. The presence of indium and of aluminium is not detected. Indium and aluminium have therefore not diffused all along the sides 212 of the bottom part 21. This 3D structure obtained by MOVPE according to this second example also has an axial architecture.

The following examples are in the context of the “top-down” approach.

According to this “top-down” approach, the bottom parts 21 can be obtained from a two-dimensional (2D) layer, for example based on GaN, previously formed. In a known manner, dense patterns substantially defining, in projection along z, the bottom parts 21 are formed by lithography on the 2D layer. An etching of this 2D layer along z then makes it possible to form the plurality of bottom parts 21. The bottom parts 21 obtained by etching can be in the form of wires oriented along z, with an aspect ratio h/Φ>1, or in the form of mesas, with an aspect ratio h/Φ≤1. The etching is here configured so that the tops 211 of two adjacent bottom parts 21 are separated from each other by a separation distance ds of less than 180 nm. This makes it possible to form the active region 22 on the tops of the bottom parts 21 by MOVPE, in an axial architecture. Thus, according to the invention, the “top-down” approach can be used to obtain the bottom parts 21. Next, the active regions 22 and then the top parts 23 are formed by MOVPE as for the “bottom-up” approach described previously, while respecting a separation distance ds of less than 180 nm between the tops 211 of two adjacent bottom parts 21. This makes it possible to obtain an axial architecture by MOVPE, without creating defects on the sides or faces 224 of the active regions. Thus, by combining the principle of the invention with a formation of the bottom parts according to the “top-down” approach, the diameters of the bottom parts 21 can be significantly augmented. The aspect ratio h/Φ of the bottom parts 21 may be less than 1, or even very much less than 1. The masking layer may be omitted.

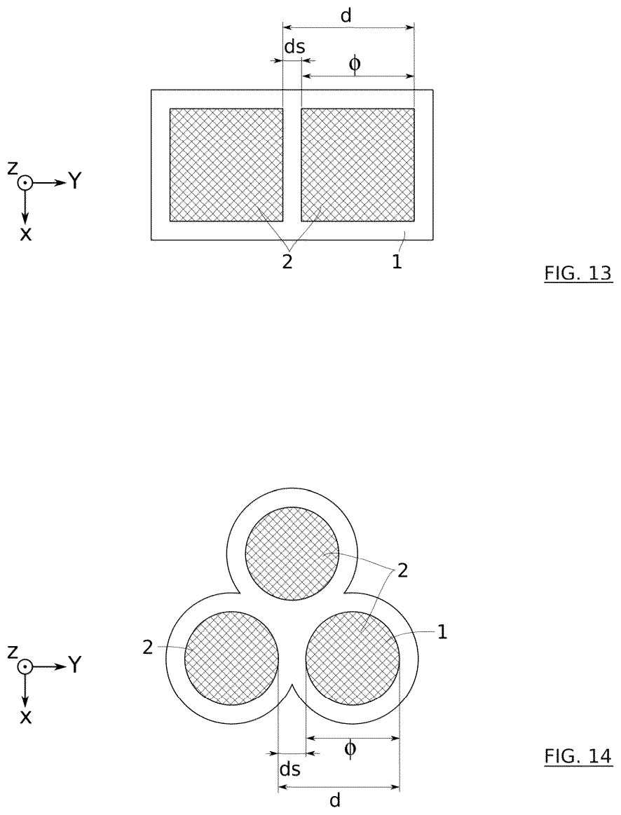

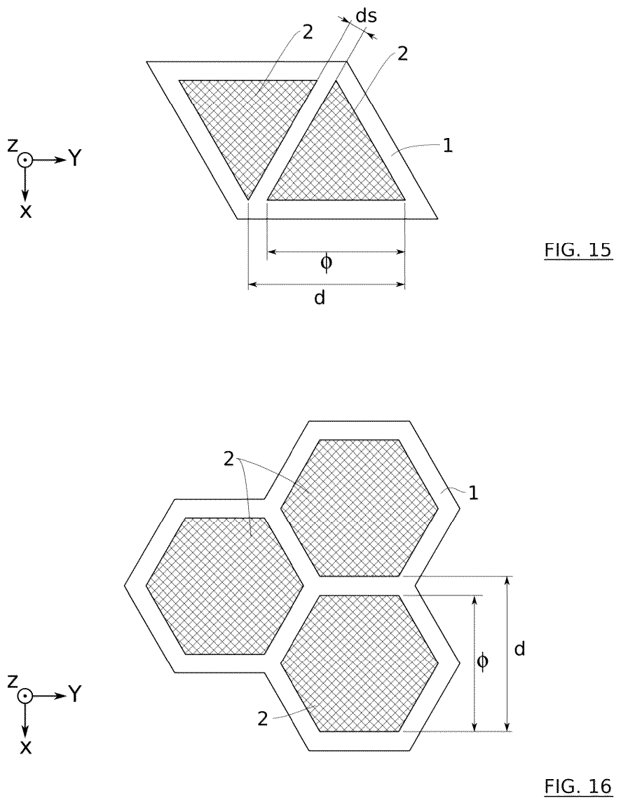

As illustrated by FIGS. 13, 14, 15, 16, various tilings or geometric arrangements of the 3D structures can be envisaged. FIG. 13 illustrates 3D structures 2 of square cross section, disposed at the surface of the substrate 1 in a square arrangement. FIG. 14 illustrates 3D structures 2 of substantially circular cross section, disposed at the surface of the substrate 1 in a compact arrangement of the hexagonal type. FIG. 15 illustrates 3D structures 2 of triangular cross section, disposed at the surface of the substrate 1 in a regular tiling. FIG. 16 illustrates 3D structures 2 of hexagonal cross section, disposed at the surface of the substrate 1 in a hexagonal tiling.

Whatever the cross-section of the 3D structures 2, a characteristic dimension Φ can be defined. The pitch of the lattice d is typically equal to the sum of this characteristic dimension Φ and of the separation distance ds, d=Φ+ds. The density of the 3D structures tiling the substrate 1 depends typically on this characteristic dimension Φ and on the separation distance ds.

It has in particular been observed in the context of the present invention that axial growth by MOVPE occurred for certain conditions of separation distance ds, and/or of the ratio

$$\frac{Φ}{Φ + ds} ,$$

or of the surface ratio

$$\frac{{S}_{2}}{{S}_{1}} ,$$

with S₂ the surface area occupied by the 3D structures on a delimited zone of the substrate, and S₁ the total surface area of the substrate on this same delimited zone. A high surface ratio, which corresponds to a degree of occupation of the 3D structures on the elevated substrate, is favourable to axial growth by MOVPE.

It has been observed that axial growth by MOVPE occurred for a separation distance ds below approximately 200 nm. Thus the separation distance ds will be selected less than 200 nm, preferably less than 180 nm, preferably less than 150 nm, and preferably less than 100 nm.

The type of arrangement selected has little influence on the conditions for obtaining axial MOVPE. The invention can therefore be implemented for various types of arrangement without departing from the principles disclosed above.

The invention is not limited to the aforementioned embodiments, and includes all the embodiments covered by the claims.

1. A method for manufacturing a plurality of three-dimensional (3D) structures for optoelectronics, each 3D structure comprising, in a stack in a longitudinal direction z:
a bottom part comprising a base bearing on a substrate,
an active region configured to emit or receive light radiation, said active region bearing on a top, opposite to the base, of the bottom part, and
a top part bearing on a top of the active region,
said method comprising:
provision of a substrate carrying a plurality of bottom parts of 3D structures, said bottom parts having distinct tops such that the tops of two adjacent bottom parts are separated from each other by a separation distance ds of less than 180 nm,
formation by metalorganic vapour-phase epitaxy (MOVPE) of the active regions on the tops of the bottom parts,
formation of the top parts on the tops of the active regions.

2. The method according to claim 1, wherein the formation by MOVPE of the active regions comprises a so-called axial deposition taking place in the longitudinal direction z and a so-called radial deposition taking place in a direction normal to the longitudinal direction z, and wherein a thickness of the radial deposit is less than or equal to 10% of a thickness of the axial deposit.

3. The method according to claim 1, configured so that the bottom part has sides with no active region.

4. The method according to claim 1, wherein the separation distance ds is less than or equal to 100 nm.

5. The method according to claim 1, wherein the bottom parts are distributed within the plurality so as to have a surface density of greater than or equal to 4 μm⁻².

6. The method according to claim 1, wherein the tops of the bottom parts have a characteristic dimension Φ, such as a diameter, taken in a plane normal to the longitudinal direction z, and wherein the separation distance ds and the characteristic dimension Φ are selected so that
$$\frac{Φ}{Φ + ds} \geq 0.6 ,$$
and preferably
$$\frac{Φ}{Φ + ds} \geq 0.8 ,$$
with 30 nm≤Φ≤550 nm.

7. The method according to claim 1, wherein the tops of the bottom parts have a characteristic dimension Φ, such as a diameter, taken in a plane normal to the longitudinal direction z, and wherein the 3D structures occupy a surface area S₂ on a delimited zone of the substrate of surface area S₁, said surface areas S₁, S₂ being selected so that
$$\frac{{S}_{2}}{{S}_{1}} \geq 0.7 ,$$
and the characteristic dimension Φ is selected so that 30 nm≤Φ≤550 nm.

8. The method according to claim 1, wherein the tops of the bottom parts have a characteristic dimension Φ, such as a diameter, taken in a plane normal to the longitudinal direction z, and wherein the separation distance ds and the characteristic dimension Φ are selected so that
$$\frac{ds}{Φ} \leq 0.75 ,$$
and preferably so that
$$\frac{ds}{Φ} \leq 0.5 .$$

9. The method according to claim 1, configured so that the active region extends solely from the top of the bottom part.

10. The method according to claim 1, wherein the bottom parts and the top parts are selected so as to be based on GaN and the active region is selected so as to be based on InGaN.

11. The method according to claim 1, wherein the active region comprises at least one quantum well based on InGaN, or a layer of InGaN with a thickness greater than 5 nm, or a set of quantum dots based on InGaN.

12. The method according to claim 11, wherein the at least one quantum well based on InGaN is formed at a temperature greater than or equal to 700° C.

13. The method according to claim 1, wherein the active region extends transversely to the longitudinal direction z.

14. The method according to claim 1, wherein the bottom part extends in the longitudinal direction z so that each 3D structure is in the form of a wire
said method further comprising:
provision of a substrate comprising at least one surface layer,
formation of a masking layer on the substrate, said masking layer comprising openings through which zones of the surface layer are exposed,
formation, from the exposed zones of the surface layer, of bottom parts in the form of wires, the bases of said bottom parts bearing on the surface layer of the substrate, through the openings,
formation, by metalorganic vapour-phase epitaxy (MOVPE) of the active regions on the tops of the bottom parts,
Formation of the top parts on the tops of the active regions.

15. An optoelectronic device comprising a plurality of three-dimensional (3D) structures being in the form of a wire and each comprising:
a bottom part extending in a longitudinal direction z and comprising a base bearing on a substrate,
an active region configured to emit or receive light radiation, said active region bearing on a top, opposite to the base, of the bottom part, and
a top part bearing on a top of the active region,
wherein the device further comprises a masking layer in contact with a surface layer of the substrate, said masking layer comprising openings through which the bottom parts in the form of a wire extend, the bases of said bottom parts bearing on the surface layer of the substrate, and in that two tops of two adjacent bottom parts are separated from each other by a separation distance ds of less than 180 nm.

16. The device according to claim 15, wherein the tops of the bottom parts of the 3D structures are separated from each other by a separation distance ds of less than or equal to 100 nm.

17. The device according to claim 15, wherein the bases have a diameter less than a diameter of the tops of the bottom parts, preferably at least 10% less.

18. The device according to claim 15, wherein the tops of the bottom parts have a characteristic dimension Φ, such as a diameter, taken in a plane normal to the longitudinal direction z, and wherein the separation distance ds and the characteristic dimension Φ are selected so that
$$\frac{Φ}{Φ + ds} \geq 0.6 ,$$
and preferably
$$\frac{Φ}{Φ + ds} \geq 0.8 ,$$
with 30 nm≤Φ≤550 nm.

19. The device according to claim 15, wherein the active region extends solely from the top of the bottom part.

20. The device according to claim 15, wherein the active region has a truncated pyramidal form.
